(19) United States
(12) Patent Application Publication
(10) Pub. No.: US 2013/0333938 A1
(43) Pub. Date: Dec. 19, 2013

(54) SHIELDED CABLE

(71) Applicant: Hiroki Kondo, Shizuoka (JP)

(72) Inventor: Hiroki Kondo, Shizuoka (JP)

(73) Assignee: YAZAKI CORPORATION, Tokyo (JP)

(21) Appl. No.: 13/983,490

(22) PCT Filed: Feb. 17, 2012
(86) PCT No.: PCT/JP12/54495

§ 371 Date: Aug. 2, 2013

(30) Foreign Application Priority Data
Feb. 17, 2011 (JP) 2011-031794

(51) Int. Cl. H05K 9/00

(52) U.S. Cl. CPC H05K 9/009
USPC 174/393

(57) ABSTRACT

A shielded cable includes: at least one conductor; an insulator with which a surface of the at least one conductor is coated, the insulator having a hardness of 10 or more and 90 or less; and a shield layer disposed on a periphery of the insulator, the shield layer being formed by braiding plated fibers.

### TECHNICAL FIELD

The present invention relates to a shielded cable.

### BACKGROUND ART

With the spread of electric vehicles and the like in recent years, a driving mechanism employing an in-wheel motor system has come to be investigated from the standpoints of ensuring an interior space and attaining the stability of the vehicle (see, for example, Patent Literatures 1 to 5). High-voltage cables for supplying power to the in-wheel motors are required to be laid in a limited space. The high-voltage cables are further required to be shielded as a measure against noises that are generated by the motors, etc.

In order to meet such requirements, shielded cables employing a spirally wound shield layer or employing a rubber-based insulator have been proposed. Furthermore, shielded cables employing a conductor which is a high-tensile-strength material have also been proposed (see, for example, Patent Literatures 6 to 10).

### CITATION LIST

### Patent Literature

Patent Literature 1: JP-A-2011-961

Patent Literature 2: JP-A-2010-221902

Patent Literature 3: JP-A-2009-96429

Patent Literature 4: JP-A-2008-1241

Patent Literature 5: JP-A-2007-276738

Patent Literature 6: JP-A-2010-225571

Patent Literature 7: JP-A-2007-311106

Patent Literature 8: JP-A-2007-311043

Patent Literature 9: JP-A-2007-305479

Patent Literature 10: JP-A-2007-299558

### SUMMARY OF INVENTION

### Technical Problem

However, the shielded cables described in Patent Literatures 6 to 10 have the following problems. Since the shield layer is constituted of metallic strands and the insulator is made of a soft rubber material, there is a possibility that the insulator might be worn by the shield-layer braid, resulting in short-circuiting between the braid and the wire disposed inside the insulator. Furthermore, there is a possibility that when strands of the braid break, the broken strands might pierce the insulator to cause short-circuiting between the strands and the internal wire. In addition, the braid does not conform to the flexibility of the internal wire and sheath, making it difficult to lay the shielded cable in a limited space.

The invention has been achieved in order to overcome such problems as mentioned above. An object of the invention is to provide a shielded cable which can be laid in a limited space and which prevents short-circuiting that occurs between the shield layer and the internal wire.

### Solution to Problem

An aspect of the invention provides a shielded cable, including; at least one conductor; an insulator with which a surface of the at least one conductor is coated, the insulator having a hardness of 10 or more and 90 or less; and a shield layer disposed on a periphery of the insulator, the shield layer being formed by braiding plated fibers.

According to the shielded cable, since the insulator has a hardness of 10 or more, the insulator can withstand vibration wear and can be prevented from being pierced by the braid. Since the hardness of the insulator is 90 or less, the shielded cable has some degree of flexibility, making it possible to lay the shielded cable in a limited space. Furthermore, the shield layer is configured of plated fibers. Since the fibers are lightweight and have highly vibration-damping properties, the insulator hence is prevented from being worn by the shield layer. Even when the plated fibers break, the broken fibers do not pierce the insulator because of the nature thereof. In addition, since the fibers are highly deformable, the shielded cable can be laid in a limited space. Thus, it is possible to provide a shielded cable which can be laid in a limited space and which is prevented from suffering short-circuiting between the shield layer and the internal wire.

In the shielded cable, the fibers may be high-tensile-strength fibers.

According to this shielded cable, since the fibers are high-tensile-strength fibers, the fibers have a strength of 2 GPa or more and the shield layer has excellent cutting resistance and excellent impact penetration resistance. This shielded cable hence can be prevented from being damaged by scattered stones or the like.

In the shielded cable, the shield layer may be formed by a braid having a braiding density of 85% or more and 98% or less, and a braid resistance of 0.096 Ω/m or less.

According to this shielded cable, since the shield layer is formed by a braid having a braiding density of 85% or more and has a braid resistance of 0.096 Ω/m or less, a shielding effect which is equal or superior to that of the conventional shield layers in general use, in terms of shielding effect determined by the absorption clamp method, can be ensured. Furthermore, since this shield layer is formed by a braid having a braiding density of 98% or less, the shield layer can have excellent flex resistance.

### Advantageous Effects of Invention

According to the aspect of the invention, it is possible to provide a shielded cable which can be laid in a limited space and which prevents short-circuiting that occurs between the shield layer and the internal wire.

### BRIEF DESCRIPTION OF DRAWINGS

FIG. 1A is a cross-sectional view of a shielded cable according to an embodiment of the invention.

FIG. 1B is a side view of the shielded cable according to the embodiment of the invention.

FIG. 2 is a graph showing the properties of shield layers.

FIG. 3 is a graph showing the flex resistance of shield layers.

### DESCRIPTION OF EMBODIMENTS

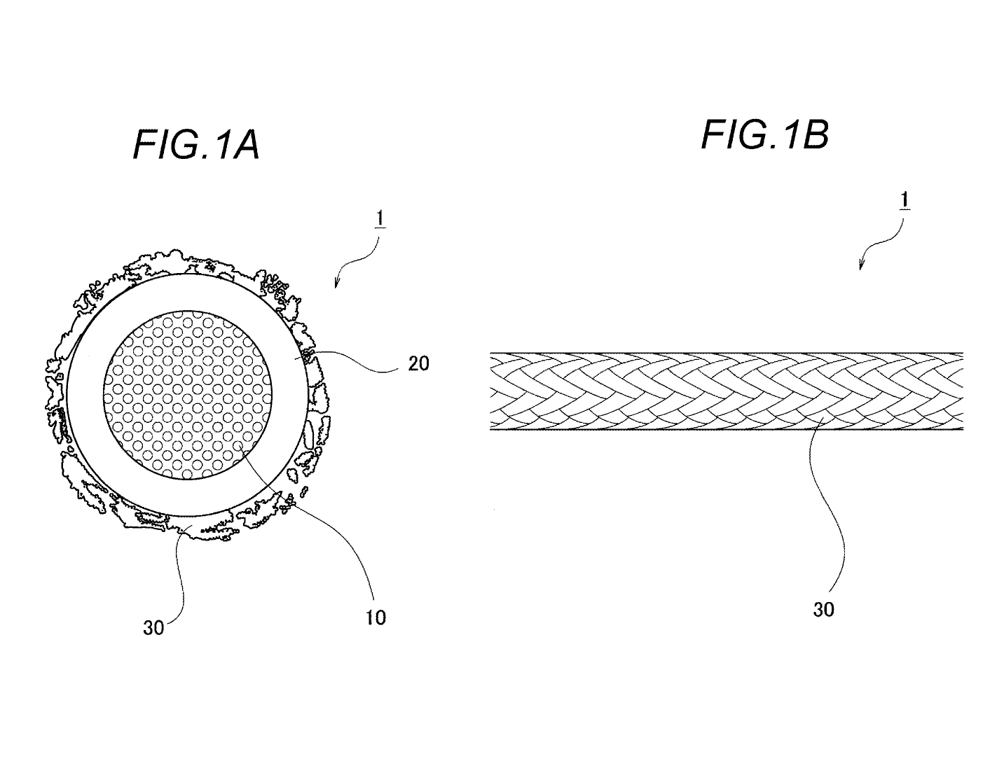

An embodiment of the invention is explained below by reference to the drawings. FIGS. 1A and 1B show the configuration of a shielded cable according to an embodiment of the invention; FIG. 1A is a cross-sectional view, and FIG. 1B is a side view. A shielded cable 1 shown in FIGS. 1A and 1B includes one conductor 10, an insulator 20 with which a surface of the conductor 10 is coated, and a shield layer 30 disposed on an outer periphery of the insulator 20.

The conductor 10 is made, for example, of an annealed copper wire, a silver-plated annealed copper wire, a tin-plated annealed copper wire, a tin-plated copper alloy wire, or the like. Although this embodiment includes one conductor 10, two or more conductors may be included. The conductor 10 has suitably set values of diameter and the like according to its specifications.

The insulator 20 is a member which is disposed so as to cover the surface of the conductor 10, and is made of a material having a hardness of 10-90. The values of hardness herein are values measured with a JIS K6253 durometer type A (Shore A; ISO 7619 durometer). Specifically, the insulator 20 is made of a silicone rubber, fluorine resin, ethylene/propylene rubber, chloroprene rubber, or the like.

The shield layer 30 is constituted of a braid of plated fibers. Specifically, the shield layer 30 is configured by preparing a plurality of bundles of plated fibers and braiding the bundles.

Since the insulator 20 has a hardness of 10 or more, the insulator 20 can withstand vibration wear and can be prevented from being pierced by the braid. Since the hardness of the insulator 20 is 90 or less, the shielded cable has some degree of flexibility, making it possible to lay the shielded cable in a limited space.

Furthermore, the shield layer 30 is configured of plated fibers. Since the fibers are lightweight and have highly vibration-damping properties, the insulator 20 hence is prevented from being worn by the shield layer 30. Moreover, since the shield layer 30 is configured of plated fibers, the fibers do not pierce the insulator 20 even when fiber breakage has occurred. In addition, since the fibers are highly deformable, the shielded cable can be laid in a limited space.

The fibers are high-tensile-strength fibers. The fibers hence have a strength of 2-8 GPa. The shield layer therefore has excellent cutting resistance and excellent impact penetration resistance, and can prevent the shielded cable from being damaged by scattered stones, etc. Examples of the high-tensile-strength fibers include para-aramid fibers, PBO (poly(p-phenylenebenezobisoxazole)) fibers, and polyarylate fibers.

The shield layer 30 is constituted of a braid having a braiding density of 85-98% and has a braid resistance of 0.096 Ω/m or less. Since the shield layer 30 is constituted of a braid having a braiding density of 85% or more and has a braid resistance of 0.096 Ω/m or less, a shielding effect which is equal or superior to that of the conventional shield layers in general use, in terms of shielding effect determined by the absorption clamp method, can be ensured.

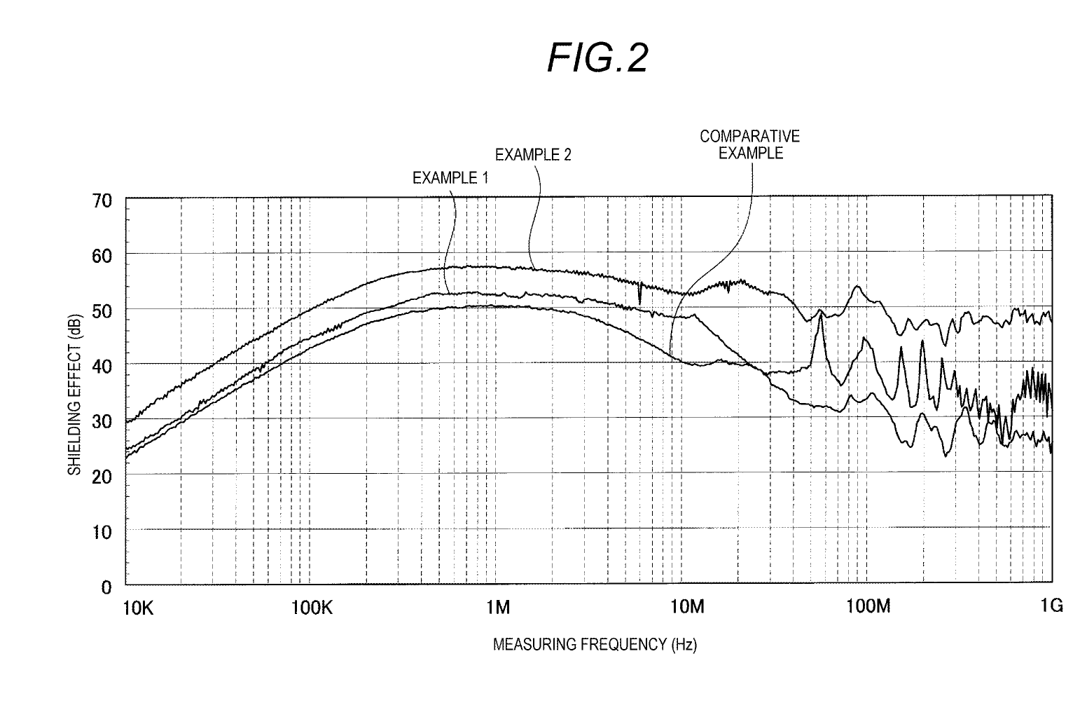

FIG. 2 is a graph showing the properties of shield layers 30. Of the Examples shown in FIG. 2, Examples 1 and 2 each are a shield layer 30 obtained by braiding twenty-four bundles each composed of polyarylate fibers (440 dtex) plated with tin and copper in any desired thickness. The shield layer of Example 1 has a braiding density of 85% and a braid resistance of 0.096 Ω/m, and the shield layer of Example 2 has a braiding density of 97% and a braid resistance of 0.052 Ω/m.

Comparative Example is a sleeve of glass fibers wrapped in a tin-plated copper foil, and the sleeve has a braiding density of 65% and a braid resistance of 0.130 Ω/m.

As shown in FIG. 2, a shielding effect of 20 dB or more was obtained throughout the frequency range of 9 kHz to 1 GHz in all of Examples 1 and 2 and Comparative Example. However, Examples 1 and 2 showed a higher shielding effect than Comparative Example. Thus, by regulating the braids so as to have a braiding density of 85% or more and a braid resistance of 0.096 Ω/m or less, a shielding effect equal or superior to that of the conventional shield layers in general use can be ensured, the shielding effect being determined by the absorption clamp method.

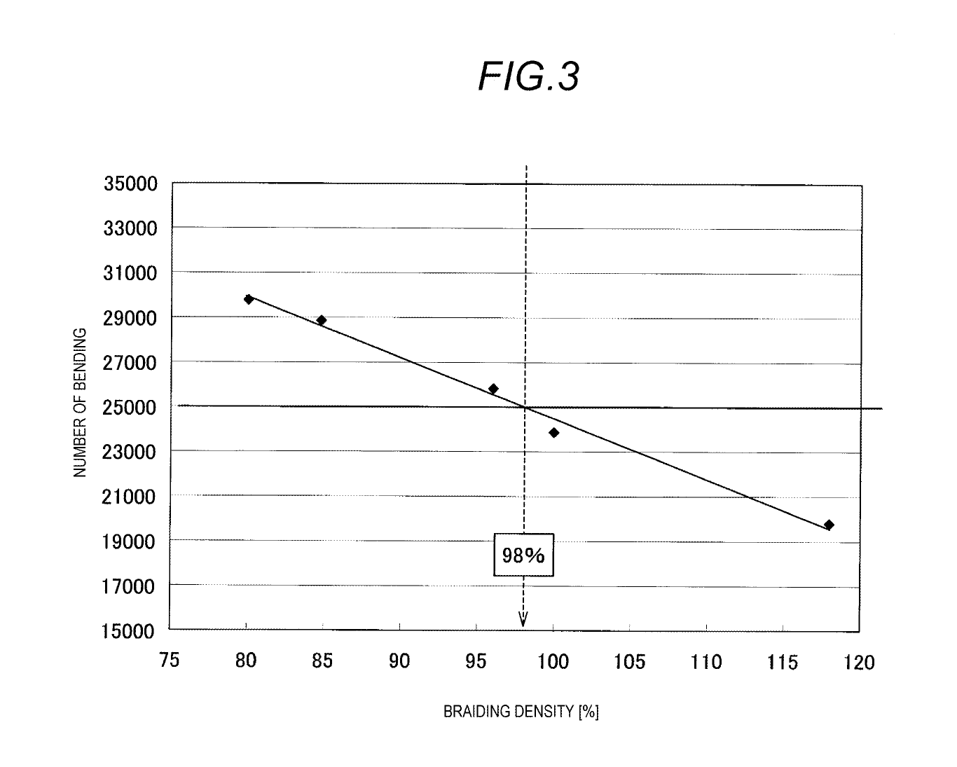

FIG. 3 is a graph which shows the flex resistance of shield layers 30. Measurements for determining the property shown in FIG. 3 are made in the following manner. Each shield layer 30 is disposed along an R-20 guide, and a load of 400 g is applied thereto. The distance between the fixed side and the moving side is adjusted to 40 mm, and the stroke and the cycling rate are set at 100 mm and 100 cycles/min, respectively. Under the condition as above, the number of cycles required for the braid resistance to increase by 10% is counted.

In the measurement, a shield layer 30 having a braiding density of 80% had a number of bending of 30,000. A shield layer 30 having a braiding density of 85% had a number of bending of 29,000. A shield layer 30 having a braiding density of 96% had a number of bending of 26,000. A shield layer 30 having a braiding density of 100% had a number of bending of 24,000. Furthermore, a shield layer 30 having a braiding density of 118% had a number of bending of 20,000.

The results show that for ensuring a number of bending of 25,000, it is necessary that the shield layer 30 should have a braiding density of 98% or less. By regulating the braiding density to 98% or less, a shield layer having excellent flex resistance can be provided.

Next, a process for producing the shielded cable 1 according to this embodiment is explained. First, the surface of a conductor 10 is extrusion-coated with an insulator 20 having a hardness of 10-90. Thereafter, the insulator 20 is covered with a shield layer 30 formed by braiding plated fibers. The shielded cable 1 is produced in this way. With respect to the production process, it is a matter of course that the number of conductors 10, etc. are changed in accordance of the specifications of the shielded cable 1 to be produced.

According to this shielded cable 1 described above as the embodiment, since the insulator 20 has a hardness of 10 or more, the insulator 20 can withstand vibration wear and can be prevented from being pierced by the braid. Since the hardness of the insulator 20 is 90 or less, the shielded cable has some degree of flexibility, making it possible to lay the shielded cable in a limited space. Furthermore, the shield layer 30 is configured of plated fibers. Since the fibers are lightweight and have highly vibration-damping properties, the insulator 20 hence is prevented from being worn by the shield layer 30. Moreover, since the shield layer 30 is configured of fibers, the fibers do not pierce the insulator 20 even when fiber breakage has occurred. In addition, since the fibers are highly deformable, the shielded cable can be laid in a limited space. Thus, the shielded cable 1 which can be laid in a limited space and can be prevented from suffering short-circuiting between the shield layer and the internal wire can be provided.

Moreover, since the fibers are high-tensile-strength fibers, the fibers have a strength of 2 GPa or more. The shield layer hence has excellent cutting resistance and excellent impact penetration resistance, and can prevent the shielded cable from being damaged by scattered stones, etc.

In addition, by configuring the shield layer 30 so that the braid has a braiding density of 85% or more and a braid resistance of 0.096 Ω/m or less, a shielding effect equal or superior to that of the conventional shield layers in general use can be ensured, the shielding effect being determined by the absorption clamp method. Since the braid constituting the shield layer has a braiding density of 98% or less, this shield layer can have excellent flex resistance.

While the invention has been explained with reference to a specific embodiment thereof, the invention should not be construed as being limited to the embodiment and modifications can be made therein without departing from the spirit thereof.

For example, the electric cable 1 according to this embodiment is not limited to high-voltage cables and may be used as an electric cable for passing a slight current. With respect to the conductor 10 and insulator 20 which have been disposed inside the shield layer 30, it is possible to change the number thereof, twisting, etc. according to requirements. Other members may be disposed on the outer periphery of the shield layer 30.

This application is based upon and claims the benefit of Japanese Patent Application No. 2011-031794 filed on Feb. 17, 2011, the contents of which are incorporated herein by reference.

### REFERENCE SIGNS LIST

1: Shielded cable
10: Conductor
20: Insulator
30: Shield layer

1. A shielded cable, comprising:
at least one conductor;
an insulator with which a surface of the at least one conductor is coated, the insulator having a hardness of 10 or more and 90 or less; and
a shield layer disposed on a periphery of the insulator, the shield layer being formed by braiding plated fibers.

2. The shielded cable according to claim 1, wherein
the fibers are high-tensile-strength fibers.

3. The shielded cable according to claim 1, wherein
the shield layer is formed by a braid having a braiding density of 85% or more and 98% or less, and a braid resistance of 0.096 Ω/m or less.
